(19) United States
(12) Patent Application Publication
(10) Pub. No.: US 2012/0120641 A1
(43) Pub. Date: May 17, 2012

(54) AUTOMATIC MAINTENANCE AND CLEANING OF SOLAR ENERGY RECEPTORS

(76) Inventor: Fathy Yassa, Soquel, CA (US)

(21) Appl. No.: 13/099,744

(22) Filed: May 3, 2011

Related U.S. Application Data
(60) Provisional application No. 61/413,404, filed on Nov. 13, 2010.

(51) Int. Cl. F21L 4/08; H01L 31/048

(52) U.S. Cl. 362/183; 136/251

(57) ABSTRACT

In one embodiment, a solar powered street lamp includes a solar panel configured to generate electric power from sunlight, a power storage device for storing the generated electric power, a light source powered by the stored electric power, and a washing system including a nozzle for directing fluid from a fluid supply at the solar panel. Optionally, a wiping system is provided and includes a wiper along with a wiper motor configured to motivate the wiper across at least a portion of the solar panel. Detergent may be provided to aid in chemical cleaning of the panel.

### PRIORITY CLAIM

Applicants hereby claim priority to U.S. Provisional Patent Application Ser. No. 61/413,404 filed Nov. 13, 2010, entitled “Method and Apparatus To Improve Efficiency of Charging and Automatic Maintenance and Cleaning of Solar Panel Receptors Used in Power Generation and in Equipment Powered by Outdoors and Remote Solar Panels,” the contents of which are incorporated herein by reference in their entirety.

### TECHNICAL FIELD

The present disclosure relates generally to solar energy receptors such as solar panels.

### BACKGROUND

With reference to FIG. 1, a solar panel 100, also known as a photovoltaic module or photovoltaic panel, operates as a solar energy receptor and is made up of a plurality of solar cells 102 that convert the energy of sunlight directly into electricity through the photovoltaic effect. Solar panels can be very effectively used in regions that experience a large number of sunny days per year, particularly deserts. Applications include powering street lamps 200, as shown in FIG. 2, whereby sunlight is converted to electricity by a panel 100, and the electricity is stored in a storage device 202 such as a battery for use for powering the lamp at night time. Other uses are also known, for example powering homes and offices using roof-installed panels and the like.

Since arid and desert regions tend to be more rural than temperate zones, the use of solar panels in these regions may be beneficial by providing electricity to these less inhabited regions that may be off an electric grid. One drawback is the presence of dust, dirt, pollen, and other airborne particulates, by themselves or mixed with rainfall, which can settle on a solar panel and obstruct the path of sunlight to its surface. Such particulates thus create an opaque film on the solar panels that can attenuate solar rays and prevent them from reaching the solar cells in the panel, thereby partially or completely interfering with their operation. In remote and sparsely populated desert regions, this is particularly problematic due to the absence of sufficient personnel to clean the panels to remove dust and other obstructions. Manual cleaning of multitudes of panels stretched out across hundreds of miles of roadway in hostile desert environments therefore become a very expensive proposition.

### OVERVIEW

As described herein, a self-cleaning solar panel system includes a solar panel configured to receive sunlight and generate electric power therefrom, a power storage device for storing the generated electric power, and a washing system including a nozzle for directing fluid at the solar panel and a microcontroller operative to control operation of the nozzle.

Also as described herein, a solar powered street lamp includes a solar panel configured to generate electric power from sunlight, a power storage device for storing the generated electric power, a light source powered by the stored electric power, and a washing system including a nozzle for directing fluid from a fluid supply at the solar panel.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIG. 1 is a diagram of a conventional solar panel receiving sunlight;

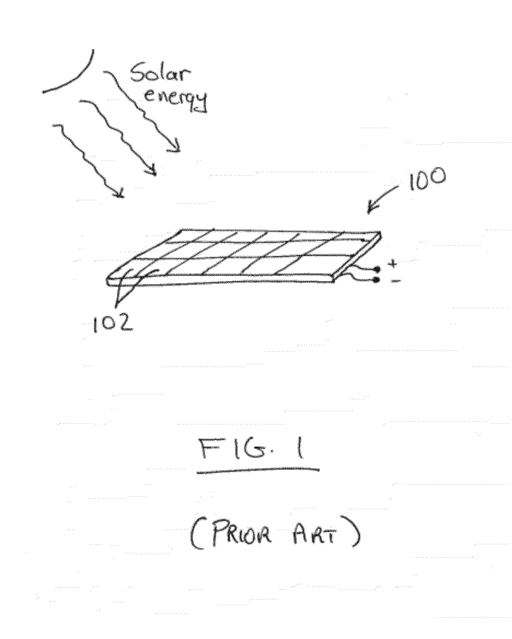

FIG. 2 is a diagram of a conventional solar panel used to power a street lamp;

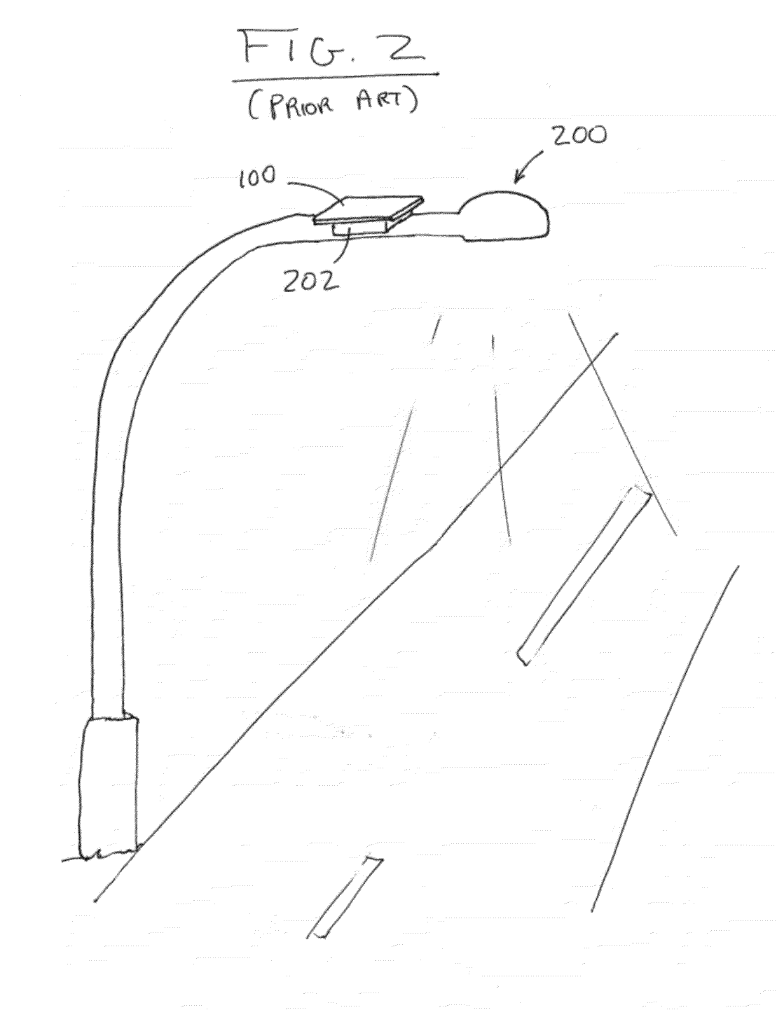

FIG. 3 is a schematic diagram of a self-cleaning solar panel system; and

FIG. 4 is a block diagram of portions of the self-cleaning solar panel system.

### DESCRIPTION OF EXAMPLE EMBODIMENTS

Example embodiments are described herein in the context of a method and apparatus for automatic maintenance and cleaning of solar energy receptors. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used to the extent possible throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

The term “exemplary” may be used herein and is exclusively intended to mean “serving as an example, instance or illustration.” Any embodiment described herein as “exemplary” is not necessarily to be construed as preferred or advantageous over other embodiments.

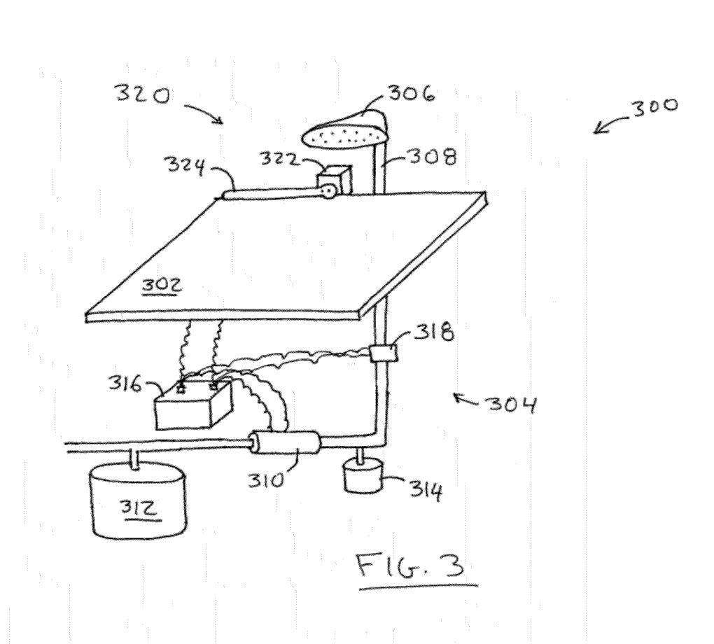

FIG. 3 is a schematic diagram of a self-cleaning solar panel system 300 for use with solar-powered devices such as street lamps. Self-cleaning solar panel system 300 includes a washing system 304 having a shower head or similar nozzle 306 directed at a solar panel 302 and serving to provide a spray or stream of water and/or detergent to wash away particulates and other obstructing material from the panel. Water is provided by way of piping 308 from a remote or local water storage tank (not shown), and may include a dedicated or shared (among multiple panels corresponding to multiple street lamps) water pump 310 to convey the water at suitable pressure to and through the shower head 306 onto the panel. In one embodiment, a first, water reservoir 312, also dedicated or shared among different washing systems associated with different panels of different lamps, can be provided to retain water for use by the washing system 304. Water reservoir 312 can be replenished from sources such as rainwater, water supply trucks, and so on. In addition, a detergent storage reservoir 314 can be provided to supply detergent for the cleaning of the panels. Actuation of the water pump 310 may be coordinated with actuation of a valve 318 that controls the flow of water (and/or detergent) to and through the shower head 306. The water pump 310 may be powered by electricity from power storage device 316, which is itself charged by the electricity generated by panel 302 during daytime operation of the panel, and which is discharged for powering the light source of the street lamp at night in a contemplated lighting application. Alternatively, the water pump and/or other components of the washing system 304 may be powered directly form the panel 302.

Also shown in FIG. 3 is a wiper system 320, configured to include suitably-shaped wipers whose action covers the surface of the panels during sweep cycles of the wipers. In wiper system 320, a motor 322 motivates a set of one or more wipers 324 to move across the panel 302, by way of a mechanical linkage (not shown) if necessary. The motor 322 may be powered by electricity from power storage device 316 and/or directly from panel 302.

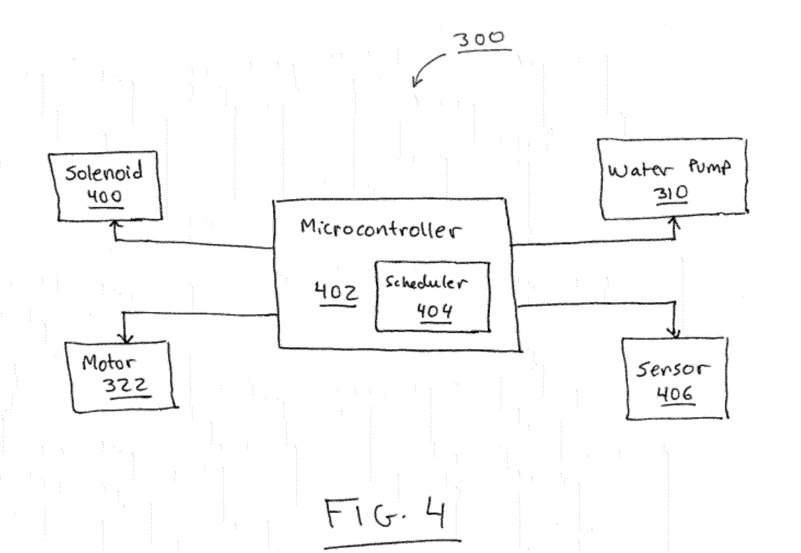

FIG. 4 is a block diagram showing some components of the self-cleaning solar panel system 300. These include a solenoid 400 for actuating the valve 318, motor 322 motivating the wipers, water pump 310, and a microcontroller 402 configured to manage the activities of the system 300, including power control activities of power storage device 316, for example for optimizing charging and discharging of the device. Microcontroller 402 may include a scheduler 404 to schedule cleaning by the system 300, selectively activating components of the washing system 304 and/or the wiper system 320 as necessary or in accordance with a pre-programmed procedure, or on command by an operator (for example during a self-test mode). Microcontroller 402 may be configured to receive information from an optional sensor 406 operative to provide an indication of the presence of obstructions such as particulates on the panel 302 to thereby trigger a cleaning cycle by the system 300 and, specifically, by the washing system 304 and/or the wiper system 320. One or more photosensors or other detectors (not shown) can be employed for this purpose, providing, in the case of photosensors, a signal indicative of the amount of light reaching them, and, conversely, the amount of obstruction encountered. It should be recognized that microcontroller may be a very basic circuit such as an FPGA or ASIC and consisting of a few discrete electronic components, or it may be a more sophisticated processor or microprocessor as is known in the art.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A self-cleaning solar panel system comprising:
a solar panel configured to receive sunlight and generate electric power therefrom;
a power storage device for storing the generated electric power; and
a washing system including a nozzle for directing fluid at the solar panel and a microcontroller operative to control operation of the nozzle.

2. The system of claim 1, wherein the washing system is powered by the generated electric power either directly from the solar panel or following storage and retrieval from the power storage device.

3. The system of claim 1, wherein the microcontroller includes a scheduler and controls operation of the nozzle in accordance with the scheduler.

4. The system of claim 1, further including a detergent-storing reservoir in fluid communication with the nozzle and serving as a source of detergent for delivery through the nozzle.

5. The system of claim 1, further including a water-storing reservoir in fluid communication with the nozzle and serving as a source of water for delivery through the nozzle.

6. The system of claim 1, further including a valve actuatable by the microcontroller and operative to govern flow of fluid through the nozzle.

7. The system of claim 1, further including a pump actuatable by the microcontroller and operative to pump fluid through the nozzle.

8. The system of claim 1, further including a sensor coupled to the microcontroller, the microcontroller configured to control the operation of the washer system based on an output of the sensor.

9. The system of claim 1, further comprising a wiping system including:
a wiper; and
a wiper motor configured to motivate the wiper across at least a portion of the solar panel.

10. The system of claim 9, wherein the wiping system is powered by the generated electric power either directly from the solar panel or following storage and retrieval from the power storage device.

11. The system of claim 9, wherein the microcontroller includes a scheduler and controls operation of the wiper motor in accordance with the scheduler.

12. The system of claim 9, further including a sensor coupled to the microcontroller, the microcontroller configured to control the operation of the wiping system based on an output of the sensor.

13. A solar powered street lamp comprising:
a solar panel configured to generate electric power from sunlight;
a power storage device for storing the generated electric power;
a light source powered by the stored electric power; and
a washing system including a nozzle for directing fluid from a fluid supply at the solar panel.

14. The solar powered street lamp of claim 13, wherein the washing system is powered by the generated electric power either directly from the solar panel or following storage and retrieval from the power storage device.

15. The solar powered street lamp of claim 13, further including a microcontroller for controlling operation of the washing system.

16. The solar powered street lamp of claim 15, wherein the microcontroller includes a scheduler and controls operation of the nozzle in accordance with the scheduler.

17. The solar powered street lamp of claim 13, further including a detergent-storing reservoir in fluid communication with the nozzle and serving as a source of detergent for delivery through the nozzle.

18. The solar powered street lamp of claim 13, further including a water-storing reservoir in fluid communication with the nozzle and serving as a source of water for delivery through the nozzle.

19. The solar powered street lamp of claim 15, wherein the washing system further includes a valve actuatable by the microcontroller and operative to govern flow of fluid through the nozzle.

20. The solar powered street lamp of claim 15, wherein the washing system further includes a pump actuatable by the microcontroller and operative to pump fluid through the nozzle.

21. The solar powered street lamp of claim 15, further including a sensor coupled to the microcontroller, the microcontroller configured to control the operation of the washer system based on an output of the sensor.

22. The solar powered street lamp of claim 13, further comprising a wiping system including:
a wiper; and
a wiper motor configured to motivate the wiper across at least a portion of the solar panel.

23. The solar powered street lamp of claim 22, wherein the wiping system is powered by the generated electric power either directly from the solar panel or following storage and retrieval from the power storage device.

24. The solar powered street lamp of claim 22, further including a microcontroller for controlling operation of the wiping system.

25. The solar powered street lamp of claim 24, wherein the microcontroller includes a scheduler and controls operation of the wiper motor in accordance with the scheduler.

26. The solar powered street lamp of claim 22, further including a sensor coupled to the microcontroller, the microcontroller configured to control the operation of the wiping system based on an output of the sensor.
